(19) United States
(12) Patent Application Publication
(10) Pub. No.: US 2006/0255404 A1
(43) Pub. Date: Nov. 16, 2006

(54) Semiconductor resistance element and fabrication method thereof

(76) Inventor: Jung-Cheng Kao, Shanghai (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 11/437,692

(22) Filed: May 22, 2006

Related U.S. Application Data
(62) Division of application No. 10/968,109, filed on Oct. 20, 2004.

(30) Foreign Application Priority Data
Oct. 24, 2003 (CN) 200310108123.9

(51) Int. Cl. H01L 29/76

(52) U.S. Cl. 257/335

(57) ABSTRACT

A semiconductor resistance element and fabrication method thereof. When polysilicon is used as a resistance element, salicides having contacts for connecting external leads are formed on two sides of the polysilicon. If the resistance element has a high resistance coefficient, an interface resistance is produced between the salicide and the block oxide layer. This interface resistance is subject to variations in voltage and temperature, resulting in unstable resistivity. The present invention provides an ion implantation with high concentration for implanting two sides of the polysilicon of the resistance element. This ion implantation with high concentration is performed before the salicides are formed. The polysilicon on two sides of the resistance element under the salicides has a lower resistance coefficient, resulting in reducing the interface resistance between the silicide and the block oxide layer.

### BACKGROUND OF THE INVENTION

1. Field of the Invention

The present invention relates to a method of fabricating a resistance element in a semiconductor, and more particularly, to a polysilicon resistance element and a fabrication method thereof.

2. Description of the Prior Art

Polysilicon is a pure silicon structure composed of various crystal orientations of small monocrystalline dies, wherein each monocrystalline die in polysilicon is separated by a grain boundary. Because there are various line defects and point defects in the grain boundaries, the diffusion ability of the dopant atoms passing through these grain boundaries is faster than that of the dopant atoms passed by the internal dies.

Because of the afore-mentioned factors, doping is performed to the polysilicon to change the electrical characteristics, thereby obtaining the required polysiliocon for the process condition. Alternatively, the fabrication of solid state electronic devices is provided for designing the electronic device with different functions by doping the dopant with the different property and concentration to adjust the polysilicon characteristics. Electronic devices with different functions are designed by the characteristic of electric variation. Therefore, polysilicon with high resistivity is used for the required resistance element in IC design.

When posilicon is used as the resistance element, as shown in FIG. 1 and FIG. 2, the salicide 12 with the contacts 25 are formed on two ends of the polysilicon layer 10 for connecting the external leads. Since the resistance element must be a non-salicide, a block oxide layer 16 is covered on the surface of the polysilicon layer 10 to prevent the salicide 12 formation. However, when the resistance element has a high resistance coefficient, such as greater than 1 KΩ/m, an interface resistance is produced between the salicide 12 and the block oxide layer 16. This interface resistance is subject to the variation in the voltage and the temperature, resulting in unstable resistivity. As shown in FIG. 3, the resistance element with P-typed high resistance is subjected to the voltage, so that the resistivity becomes unstable.

In the view of this, the present invention provides a semiconductor resistance element and fabrication method thereof, which reduces the interface resistance to effectively overcome the problems that exist in the prior art.

### SUMMARY OF THE INVENTION

The present invention provides a semiconductor resistance element and fabrication method thereof, in which ion doping areas with high-concentration are respectively formed on two ends of the resistance element, so that the polysilicon layer on two ends of the resistance element has the lower resistance coefficient, resulting in reducing the interface resistance between the silicide and the block oxide layer.

By reducing the interface resistance between the silicide and the block oxide layer results in reducing the resistance element being subjected to variations in the voltage and temperature, in order to solve unstable resistivity.

A polysilicon layer is formed on the semiconductor substrate. Two salicides are formed on two sides of the polysilicon layer. A block oxide layer is formed on the surface of the polysilicon layer between the two salicides. An ion implantation is performed to respectively form the doping areas with high concentration in the polysilicon layer under the two salicides. Chemical vapor deposition is performed to form an oxide layer to cover the surface of the block oxide layer and the salicides, exposing the portion of the salicides used as contacts.

First, a polysilicon layer is formed on a semiconductor substrate. A patterned block oxide layer is formed on the polysilicon layer. Using the patterned block oxide layer as a mask, an ion implantation is performed on the semiconductor substrate to respectively form doping areas in the polysilicon layer on two sides of the patterned block oxide layer. Using this patterned block oxide layer as a mask, a salicide process is performed to form a layer of salicide on the surface of the polysilicon layer on two sides of the patterned block oxide layer. Finally, an oxide layer is deposited over the surface of the patterned block oxide layer and the oxide layer, exposing the portion of the salicides used as contacts.

These and other objectives of the present invention will become obvious to those of ordinary skill in the art after reading the following detailed description of the preferred embodiment.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a cross-sectional view of a conventional resistance element;

FIG. 2 is a top view of a conventional resistance element;

FIG. 3 shows a graph representing the result of the conventional resistance element subjected to voltage variations;

FIG. 4 is a cross-sectional view of a resistance element according to an embodiment of the present invention;

FIG. 5 is a top view of a resistance element according to an embodiment of the present invention;

FIGS. 6a to 6d are sectional diagrams illustrating a resistance element of each step according to a preferred embodiment of the present invention; and

FIG. 7 shows a graph representing the result of a resistance element subjected to the voltage variations according to a preferred embodiment of the present invention.

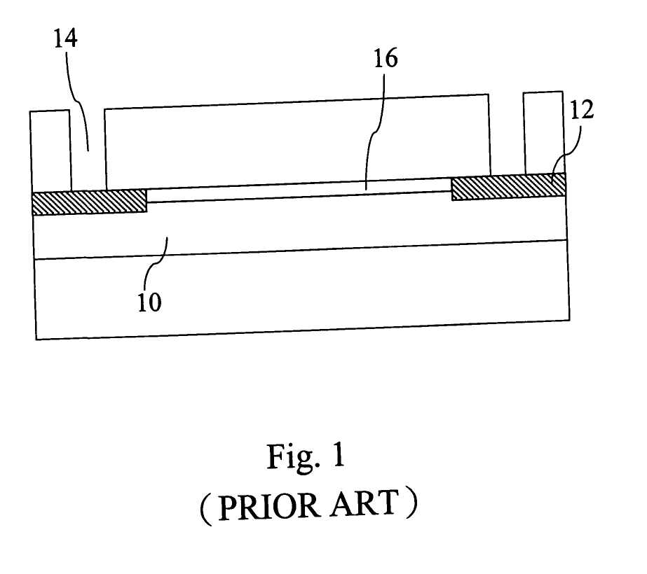

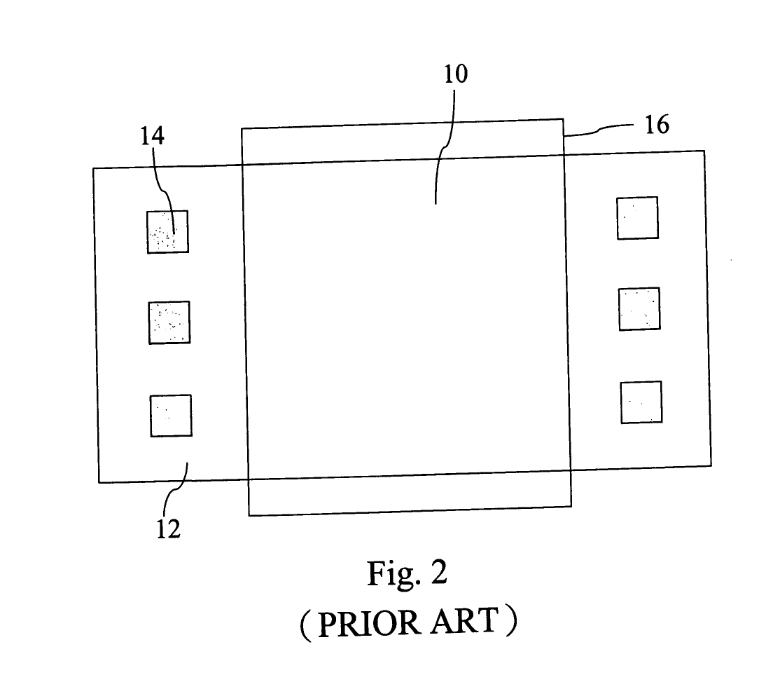

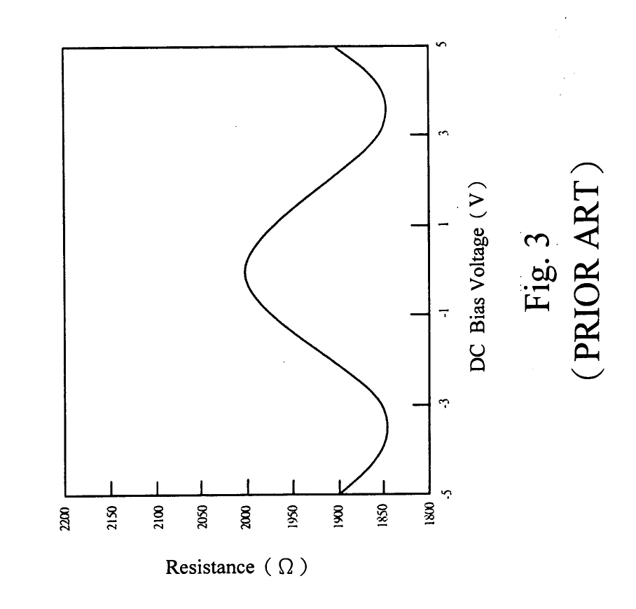

### DETAILED DESCRIPTION OF THE PREFERRED EMBODIMENTS

The present invention provides a semiconductor resistance element and fabrication method thereof, in which an ion implantation is performed before salicides are formed on two ends of the resistance element, in order to reduce the interface resistance between the salicides and the block oxide layer.

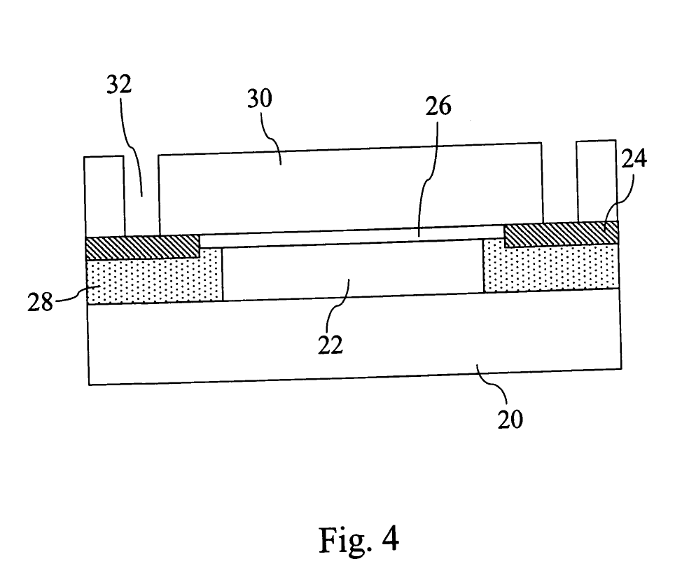

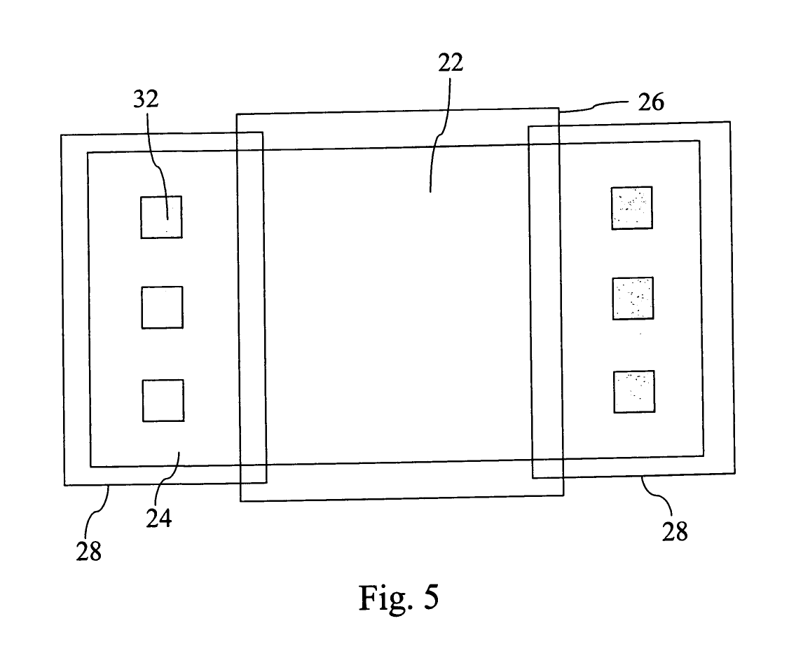

As shown in FIGS. 4 and 5, a polysilicon layer 22 is formed on the semiconductor substrate 20. Two salicides 24 are respectively formed on two sides of the polysilicon layer 22. A block oxide layer 26 is formed between the two salicides 24 on the surface of polysilicon layer 22. Ions are implanted into the polysilicon layer 22 by ion doping with high concentration under the two salicides 24, forming two ion doping areas 28 with high concentration. The doping concentration is about 10¹⁵/square centimeters. An oxide layer 30 is formed by chemical vapor deposition (CVD) to cover the surface of block oxide layer 26 and the two salicides 24, exposing a portion of the salicide 24 used as contacts 32.

When the ion implantation with high concentration is performed, if the afore-mentioned resistance element is N-typed resistance, an N-typed dopant is implanted into the ion doping areas 28. Alternatively, if the afore-mentioned resistance element is P-typed resistance, a P-typed dopant is implanted into the ion doping areas 28, and the doping concentration is about 10¹⁵/square centimeter.

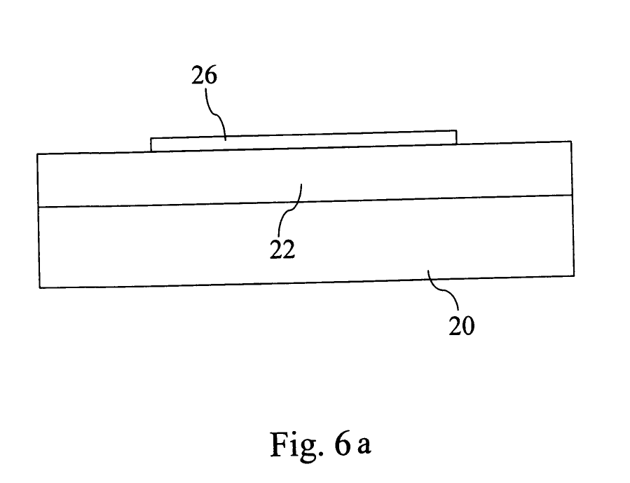

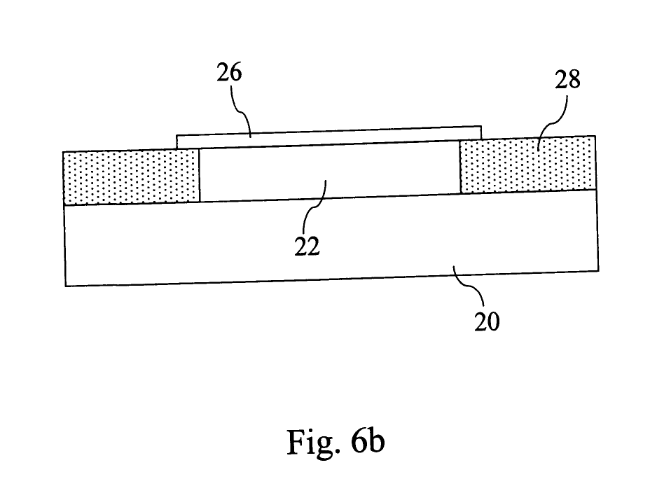

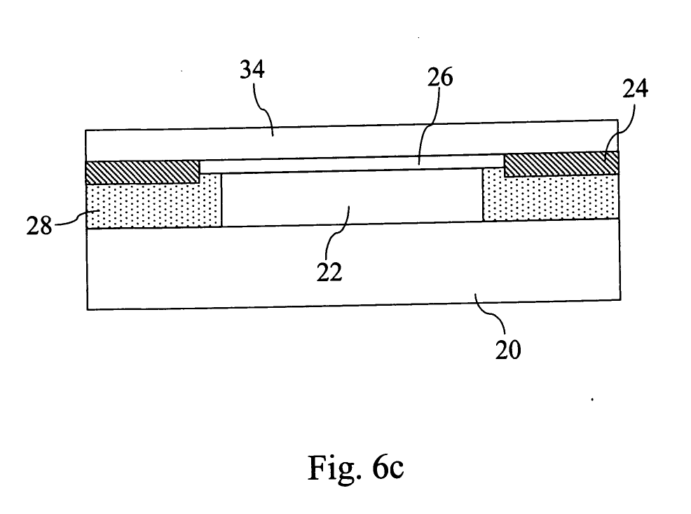

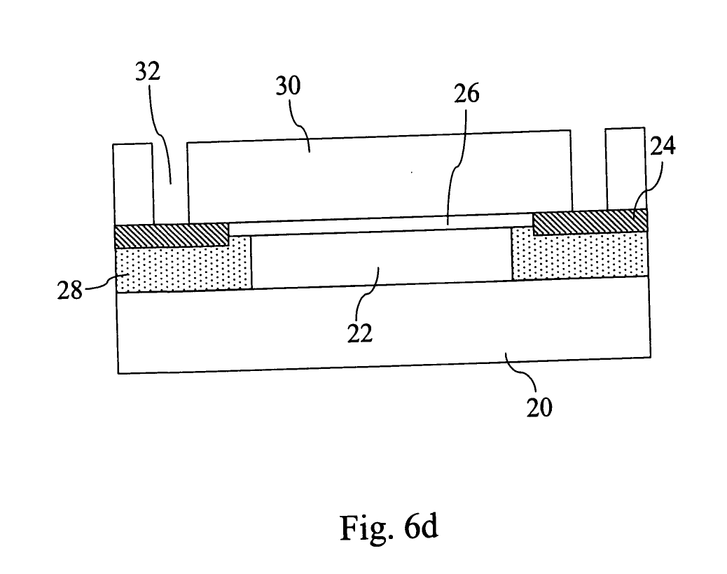

FIG. 6a to FIG. 6d, show the resistance element of each step according to a preferred embodiment of the present invention.

As shown in FIG. 6a, first, a polysilicon layer 22 is formed on a semiconductor substrate 20. A patterned block oxide layer 26 used as a salicide block is formed on surface of the polysilicon 22 by using chemical vapor deposition (CVD) and lithography processing. The thickness is between 200 and 2000 angstroms. This patterned block oxide layer 26 is used for preventing silicide formation from the subsequent salicide process.

Using the patterned block oxide layer 26 as a mask, an ion implantation with high concentration is performed on the semiconductor substrate 20, shown in FIG. 6b, forming the N-typed or P-typed doping areas 28 with high concentration in the polysilicon layer 22 on two sides of the patterned block oxide layer 26. Then, a rapid thermal anneal (RTA) is performed. And a salicide process is performed.

Referring to FIG. 6c, a metal layer 34 is formed on the surface of the polysilicon layer 11 and the patterned block oxide layer 26 by sputtering. The first RTA process is performed again to produce the silicidation reacted with the contacted surface of the metal layer 34 and the exposed polysilicon layer, resulting in the salicide 24. The unreacted or remaining metal layer 34 is selectively removed by a wet etching process. A second RTA process is performed, thereby forming the stable salicide structure 24 on the semiconductor substrate 30 as shown in FIG. 6d.

Finally, as shown in FIG. 6d, an oxide layer 20 is deposited on the semiconductor substrate 30 by using chemical vapor deposition (CVD) to cover the surface of the patterned block oxide layer 26 and the salicide 24, exposing the portion of the salicide 24 used as the contacts 32 for electrically connecting with the external leads.

The material of the silicide is cobalt, titanium, nickel, palladium, or platinum or the like, and the silicide formation is cobalt silicide, titanium silicide, nickel silicide, palladium silicide, or platinum silicide or similar silicides.

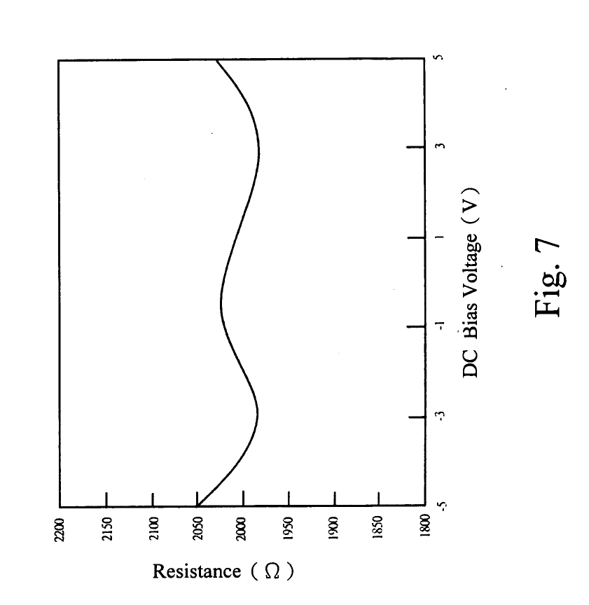

According to the present invention, prior to the salicide formation on two sides of the resistance element, an ion doping area with high concentration is formed by doping, resulting in the polysilicon on two sides of resistance element with a lower resistance coefficient. The interface resistance between the silicide and the block oxide layer is greatly reduced, and also the resistance element is decreasingly subjected to variations in the voltage and temperature. As shown in FIG. 7, the resistance element subjected to the voltage becomes more stable to solve the unstable resistivity caused by the resistance element being subjected to the variations in the voltage and temperature.

The embodiment above is only intended to illustrate the present invention; it does not, however, to limit the present invention to the specific embodiment. Accordingly, various modifications and changes may be made without departing from the spirit and scope of the present invention as described in the following claims.

1-7. (canceled)

8. A fabrication method of a semiconductor resistance element, comprising: forming a polysilicon layer on a semiconductor substrate; forming a patterned block oxide layer on the surface of the polysilicon layer; performing an ion implantation with a high concentration by using the patterned block oxide layer as a mask to form an ion doping area respectively in the polysilicon layer on two sides of the patterned block oxide layer; forming a layer of silicide on the surface of the polysilicon layer on two sides of the patterned block oxide layer by using the patterned block oxide layer as a mask; and depositing an oxide layer on the semiconductor substrate covered on the surfaces of the patterned block oxide layer and two silicides, and exposing a portion of the silicides for use as contacts.

9. The fabrication method of the semiconductor resistance element of claim 8, wherein the semiconductor resistance element is N-typed resistance and an N-typed dopant with high concentration is implanted into the ion doping areas.

10. The fabrication method of the semiconductor resistance element of claim 8, wherein the semiconductor resistance element is P-typed resistance and a P-typed dopant with high concentration is implanted into the ion doping areas.

11. The fabrication method of the semiconductor resistance element of claim 8, wherein the doping concentration of the ion doping area is greater than 10.sup.15/square centimeters.

12. The fabrication method of the semiconductor resistance element of claim 8, wherein the suicides are the salicides.

13. The fabrication method of the semiconductor resistance element of claim 12, wherein the step of forming the salicides further comprises: forming a metal layer on the semiconductor substrate; performing a thermal process to produce a silicidation reacted with the contacted surface of the metal layer and the polysilicon layer to form the salicides; and removing the metal layer of unreacted silicides.

14. The fabrication method of the semiconductor resistance element of claim 13, wherein the step of performing the thermal process is achieved by a rapid thermal anneal process.

15. The fabrication method of the semiconductor resistance element of claim 13, wherein the step of removing the metal layer of unreacted suicides is achieved by wet etching.

16. The fabrication method of the semiconductor resistance element of claim 13, wherein after the step of forming the salicides, performing a rapid thermal anneal process to form the stable salicides.

17. The fabrication method of the semiconductor resistance element of claim 8, wherein the material of the silsicides is selected form the group consisting of cobalt silicide, titanium silicide, nickel silicide, palladium silicide, and platinum silicide.

18. The fabrication method of the semiconductor resistance element of claim 8, wherein the oxide layer is formed by chemical vapor deposition.
